(19) United States
(12) Patent Application Publication
(10) Pub. No.: US 2024/0084171 A1
(43) Pub. Date: Mar. 14, 2024

(54) ORGANIC LAYER POLISHING COMPOSITION AND METHOD FOR POLISHING USING SAME

(71) Applicant: DONGJIN SEMICHEM CO., LTD., Incheon (KR)

(72) Inventors: Hee Suk KIM, Hwaseong-si (KR); Goo Hwa LEE, Hwaseong-si (KR); Jae Hong YOO, Hwaseong-si (KR); Jong Dai PARK, Hwaseong-si (KR); Jae Hyun KIM, Hwaseong-si (KR)

(21) Appl. No.: 18/512,948

(22) Filed: Nov. 17, 2023

Related U.S. Application Data
(63) Continuation-in-part of application No. PCT/KR2022/008090, filed on Jun. 8, 2022.

(30) Foreign Application Priority Data
Jun. 8, 2021 (KR) 10-2021-0074283

(51) Int. Cl. C09G 1/02

(52) U.S. Cl. CPC C09G 1/02

(57) ABSTRACT

The present disclosure relates to an organic film polishing composition in which a high polishing speed is maintained not only for polymers, an SOC, and an SOH, but also for organic films strongly bonded by covalent bonds such as an amorphous carbon layer (ACL) or a diamond-like carbon (DLC) by including a polishing accelerator containing both a hydrophilic group and a hydrophobic group, and a polishing method using the same.

### CROSS-REFERENCE TO RELATED APPLICATIONS

This application is a Continuation in-part of International Application No. PCT/KR2022/008090 filed Jun. 8, 2022, which claims priority from Korean Application No. 10-2021-0074283 filed Jun. 8, 2021. The aforementioned applications are incorporated herein by reference in their entireties.

### TECHNICAL FIELD

The present disclosure relates to an organic film polishing composition and a polishing method using the same.

### RELATED ART

While the size of devices gradually decreases, and the required performance increases as semiconductor technologies develop, research requiring miniaturization of the line width and high integration of the devices is rapidly progressing.

In order to achieve higher integration of semiconductor devices, multi-layer stacking technology that enables stacking of circuits upward and a hard mask with a higher thickness are required. This is because, when a tall structure is made using a photoresist (PR) with a thick thickness as before, the aspect ratio increases so that the PR pattern collapses.

In order to solve the above problem, PR is patterned using a hardmask using a spin on carbon (SOC) or a spin on hardmask (SOH) and an amorphous carbon layer (ACL) as a sacrificial film, but an SOC and an SOH using spin coating have poor etch resistance compared to an ACL of a chemical vapor deposition (CVD) method, and are not suitable for devices that require increasingly thicker hard masks.

Therefore, there is an increasing demand to use ACL hard masks of the CVD method in the process of highly integrated next-generation devices, but the CVD method uses chemical vapors, and thus clusters or carbon particles generated by agglomeration of the chemical vapors are formed on the surface of ACL, and these particles cause a decrease in yield and productivity as a result.

In order to solve the above problems, a chemical mechanical polishing (CMP) technology having uniform flatness by polishing the ACL surface is required, but a CMP slurry composition that can effectively polish the ACL has not yet been developed.

Usually, an ACL is chemically inert since the carbon-carbon bond is strong, and there is a problem in that, as the CVD temperature increases, polishing of ACL with high hardness becomes more difficult.

### SUMMARY

In order to solve the problems of the conventional art as described above, an object of the present disclosure is to provide an organic film polishing composition that can implement high polishing speed and excellent polishing quality even on hard carbon-based films such as ACL.

Another object of the present disclosure is to provide a polishing method capable of implementing a high polishing speed and excellent polishing quality using the organic film polishing composition.

In order to solve the above problems, an organic film polishing composition according to an aspect of the present disclosure includes abrasive particles, a polishing accelerator, and a solvent. The polishing accelerator contains a hydrophilic group and a hydrophobic group having 5 to 30 carbon atoms, and the surface charge of the abrasive particles is opposite to the charge of the hydrophilic group of the polishing accelerator.

The abrasive particles may contain silica, and the surface thereof may be modified. For example, the surface of the abrasive particles may have aluminium contained therein, and specifically, the abrasive particles may have aluminium clusters coated on the surface of the abrasive particles. In some embodiments, the abrasive particles may contain abrasive particles, the surface of which is modified. In some examples, the abrasive particles may contain first abrasive particles, the surface of which is modified, and second abrasive particles, the surface of which is not modified. Specifically, a content of the first abrasive particles may be more than 80% by weight, more than 85% by weight, more than 90% by weight, more than 95% by weight, more than 98% by weight, or more than 99% by weight based on the total weight of the abrasive particles. When the content of the first abrasive particles satisfies the above numerical range, the stability of the polishing composition can be further improved.

The organic film polishing composition may include 1 to 20% by weight of the abrasive particles.

The hydrophobic group of the polishing accelerator may include a carbon backbone having 7 to 28 carbon atoms, and may be contained in an amount of 5 to 200 ppm based on the organic film polishing composition.

A polishing method according to another aspect of the present disclosure is a method of polishing using the organic film polishing composition.

When the organic film polishing composition according to the present disclosure is used, a high polishing speed can be implemented while minor defects or scratches in the polishing film quality occur not only with respect to a polymer, an SOC, and an SOH, but also with respect to organic films that are strongly bonded by covalent bonds, such as an amorphous carbon layer (ACL) or a diamond-like carbon (DLC).

In addition, when the organic film polishing composition according to the present disclosure is used, the debris of the polishing film is not easily bonded to the surface of the polishing film again so that there are effects that the polishing film debris can be easily discharged, and the process efficiency can be improved.

In addition, when the organic film polishing composition is used, there is an effect capable of implementing a high polishing speed along with excellent polishing quality even under low pressure for organic films that are strongly bonded by covalent bonds, such as an ACL or a DLC.

### BRIEF DESCRIPTION OF THE DRAWINGS

FIG. 1 schematically shows a structure with a modified surface as an example of an abrasive particle.

FIG. 2 schematically shows one embodiment of a polishing accelerator of the present disclosure.

FIG. 3 schematically shows a mechanism for polishing an organic film using an organic film polishing composition according to one embodiment of the present disclosure.

FIG. 4 shows CMP waste liquids after polishing an amorphous carbon layer (ACL) with organic film polishing compositions according to Examples and Comparative Examples of the present disclosure, respectively.

### DETAILED DESCRIPTION

The terms or words used in this specification and claims should not be construed as being limited to ordinary or dictionary meanings, and they should be interpreted as meanings and concepts consistent with the technical ideas of the present disclosure based on the principle that the inventor can appropriately define the concepts of the terms in order to explain his or her invention in the best way.

Therefore, since the configurations shown in Examples and Preparation Examples described in this specification are only one of the most preferred embodiments of the present disclosure, and do not represent all of the technical ideas of the present disclosure, it should be understood that there may be various equivalents and modifications that can be substituted for them at the time of this application.

Hereinafter, with reference to the drawings, the Examples of the present disclosure will be described in detail so that those skilled in the art to which the present disclosure pertains can easily implement the present disclosure. However, the present disclosure can be implemented in many different forms and is not limited to the Preparation Examples and Examples described herein.

The organic film polishing composition according to one embodiment of the present disclosure includes abrasive particles, a polishing accelerator, and a solvent. The polishing accelerator contains a hydrophilic group and a hydrophobic group having 5 to 30 carbon atoms, and the surface charge of the abrasive particles is characterized by being opposite to the charge of the hydrophilic group of the polishing accelerator. The surface charge of the abrasive particles may be measured by measuring the zeta potential of a dispersion in which abrasive particles are dispersed in an aqueous solution of a specific pH using a zeta potential meter (e.g., Anton Paar's litesizer 500). The charge of the hydrophilic group of the polishing accelerator may be measured using a zeta potential meter (e.g., Anton Paar's Surpass3) targeting a polishing target film (flat sample) onto which the polishing accelerator is adsorbed after inducing the polishing accelerator so that it is to be absorbed onto the polishing target film by loading a measurement solution in which the same amount of a polishing accelerator as the polishing accelerator in the organic film polishing composition (slurry) is added to an aqueous solution on the surface of the polishing target film.

Conventional abrasives that perform chemical mechanical polishing (CMP) may be used as the abrasive particles, the abrasive particles being particles that have a surface charge, and may be one of which the surface is modified, but may be one of which the surface is not modified. The type of the abrasive particles is not particularly limited, but examples thereof may include alumina, ceria, titania, zirconia, and silica. Among them, it may be preferable to include silica, which has a thermodynamically stable surface and an easily modifiable surface through strong adsorption or covalent bonding, and types of silica may include colloidal silica and fumed silica.

The abrasive particles are materials that have an electrical charge on the surface, and the surface of the abrasive particles has a charge that is opposite to the charge of the hydrophilic group of the polishing accelerator, which will be described later, so that the abrasive particles may more easily approach the polishing target through electrostatic attraction.

In order for the abrasive particles to more easily approach the polishing target due to electrostatic attraction, the surface of the abrasive particles may be modified. Specifically, the zeta potential of surface-modified abrasive particles may be significantly improved compared to the surface-unmodified state, which may serve as a factor in improving polishing performance.

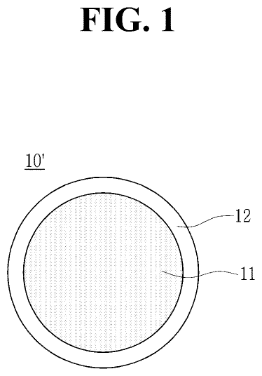

FIG. 1 schematically shows a structure with a modified surface as an example of an abrasive particle 10.

Referring to FIG. 1, the surface-modified abrasive particle 10 may be largely divided into a central part 11 and a surface part 12 surrounding the surface of the central part 11. At this time, the surface part 12 does not necessarily surround the entire surface of the central part 11, and a portion of the central part 11 may be partially exposed to the outside.

The central part 11 of the surface-modified abrasive particle 10 may be a conventional abrasive that performs chemical mechanical polishing (CMP), and may be a silica-based abrasive containing, for example, silica, and as a specific example, colloidal silica or fumed silica may be used, but it is not limited to the above examples.

The surface part 12 of the surface-modified abrasive particle 10 may be modified with a modifier containing various metal compounds in order to increase the surface charge, and a modifier containing an aluminium compound is used in order to make the surface have a strong positive charge, and thus the abrasive particle surface part 12 may be allowed to contain aluminium.

When the abrasive particle surface part 12 contains aluminium, it has a positive charge (+), and in this case, it is effective in polishing the organic film that the hydrophilic group of the polishing accelerator has a negative charge (−).

Specifically, aluminium of the abrasive particle surface part 12 may be in the form of aluminium clusters, and more specifically, the abrasive particles may be in the form of aluminium clusters coated on the surface. Abrasive particles surface-modified to include aluminium on the surface may have a strong positive charge on the particle surface, and if aluminium is coated on the surface of the abrasive particles in the form of a cluster, an even stronger positive charge may be expressed, and it may achieve higher polishing speeds, good polishing quality with fewer defects or scratches, and high polishing selectivity through the surface modification.

In addition to the aluminium compounds as the modifier, aluminium chloride, aluminium sulfate, ammonium aluminium sulfate, aluminium potassium sulfate, aluminium nitrate, trimethylaluminium, aluminium phosphide, or the like may be used, and at least one of the above examples may be selected and used, but the present disclosure is not limited to the above examples.

The aluminium clusters are not limited in type, and may include a cationic complex containing aluminium. The aluminium clusters may especially include one or more cation complex structures among [Al(OH)]²⁺, [Al(OH)₂]⁺, [Al₂(OH)₂(H₂O)₈]⁴⁺, [Al₁₃O₄(OH)₂₄(H₂O)₁₂]⁷⁺, and [Al₂O₈Al₂₈(OH)₅₆(H₂O)₂₆]¹⁸⁺, and if two or more types of aluminium cluster cation complexes are included, polishing performance may be significantly improved. The counter anion of the cation complex is not limited and may be, for example, SO₄²⁻, NO₃⁻, P⁻, or the like.

The modifier may be used in an amount of 0.02 to 5% by weight based on the total weight of the organic film polishing composition when the abrasive particles are 0.1 to 20% by weight of the total weight of the organic film polishing composition. Specifically, when the abrasive particles are 0.5 to 10% by weight of the total weight of the organic film polishing composition, the modifier may be used in an amount of 0.03 to 4% by weight based on the total weight of the organic film polishing composition, but is not particularly limited to the above example. However, within the above-described weight range, the degree of polishing uniformity of the polishing composition is particularly excellent, and the polishing amount may be further improved.

The surface-modified abrasive particles 10 may be formed, for example, by coating an aluminium cluster on a portion or the entirety of the material surface of the central part 11 of the abrasive particles. The form of the coating is not limited, and may be formed in covalent bonds between the abrasive particle central part 11 material and the aluminium cluster (condensation bond between the hydroxyl group of the abrasive particle central part 11 material and the hydroxyl group of the aluminium cluster, etc.), ionic bond, and physical bond.

An example of a method of forming surface-modified abrasive particles 10 by coating an aluminium cluster on the abrasive particle central part 11 may include the steps of preparing an aqueous dispersion by putting an aluminium compound and silica particles into water and performing a surface modification reaction with abrasive particles 10 coated with an aluminium cluster by stirring the aqueous dispersion. Water may be deionized water. The aluminium compound may be added to deionized water to prepare a solution, and silica particles may be added to the solution to prepare an aqueous dispersion in which the silica particles are dispersed. Here, the aqueous dispersion includes not only a form in which the abrasive particles are uniformly dispersed in water, but also a form in which the abrasive particles are heterogeneously dispersed. Here, the modification reaction may have a pH of 3.0 to 6, specifically, a pH of 3.0 to 5.7, and more specifically, 4.0 to 5.5. The type of an aluminium cluster obtained may vary, and the structure of the surface-modified abrasive particles may vary depending on the pH value of the modification reaction.

The pH regulator for controlling the pH of the abrasive particle modification reaction is not limited, and two or more types of pH regulators may also be used together. Examples of the types of the pH regulator may include acidic regulators such as nitric acid, hydrochloric acid, sulfuric acid, acetic acid, formic acid, and citric acid, and basic regulators such as potassium hydroxide, sodium hydroxide, tetramethylammonium hydroxide, and tetrabutylammonium hydroxide. The pH regulator can be used to control pH during the modification reaction, and may also be used to adjust the pH of the final polishing composition to suit the polishing process.

The content of the abrasive particles is not particularly limited, but specifically, the abrasive particles may be contained in an amount of 0.1 to 20% by weight, specifically 1 to 20% by weight, more specifically 3 to 15% by weight, and even more specifically 5 to 10% by weight based on the total organic film polishing composition. If the content of abrasive particles is 0.1% by weight or more based on the total weight of the polishing composition, the polishing profile (uniformity) may be greatly improved, and if it is 1% by weight or more, a particularly excellent profile may be realized, and if it is 20% by weight or less, defects and scratches of the polishing film quality are insignificant, and thus the polishing quality and polishing amount may become excellent.

The polishing accelerator contains a hydrophilic group having a charge and a hydrophobic group having 5 to 30 carbon atoms.

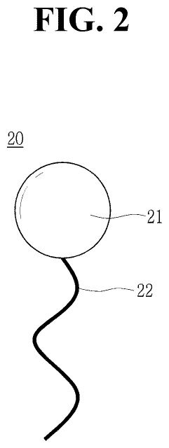

FIG. 2 schematically shows one embodiment of a polishing accelerator of the present disclosure. However, the polishing accelerator is not limited to the form disclosed in FIG. 2.

Referring to FIG. 2, the polishing accelerator 20 may be divided into a hydrophilic group 21 and a hydrophobic group 22. In order to make the electrostatic attraction of the polishing accelerator more effective, the hydrophobic group 22 may include 5 to 30 carbon atoms, specifically 7 to 28 carbon atoms, more specifically 7 to 16 carbon atoms, and more specifically 8 to 13 carbon atoms. At this time, the structure of the hydrophobic group is not particularly limited, but may be in the form of a carbon chain, for example. In addition, the chain may be in a branched form. When the number of carbon atoms of the hydrophobic group 22 is less than 5, the hydrophobic interaction of the hydrophobic group decreases, making it more difficult for the polishing accelerator to be stably positioned on the surface of the organic film, which is a polishing target, so that it may be more difficult to expect the improvement in the polishing speed by the polishing accelerator 20. On the contrary, when the number of carbon atoms of the hydrophobic group is more than 30, while the proportion of the freely movable hydrophobic group 22 in the polishing accelerator grows larger, the solubility and dispersity of the polishing accelerator 20 in the polishing composition decrease. Even if the polishing accelerator is located on the surface of organic film, a problem in which the polishing speed cannot be improved due to steric hindrance may occur.

The hydrophobic group 22 of the polishing accelerator 20 may be, for example, a chain structure, and may include a carbon backbone of 7 to 28 carbon atoms, and the carbon backbone within the above carbon number range may have a particularly high solubility of the polishing accelerator in the composition, and due to this, the stability of the organic film polishing composition may increase to provide excellent polishing speed. The hydrophobic group 22 of the polishing accelerator 20 may have specifically a carbon backbone of 7 to 16 carbon atoms, more specifically a carbon backbone of 8 to 14 carbon atoms, and even more specifically a carbon backbone of 8 to 12 carbon atoms. The polishing accelerator having a carbon backbone having the specific carbon number may have a particularly excellent hydrophobic interaction within the polishing composition, thereby further improving the polishing speed.

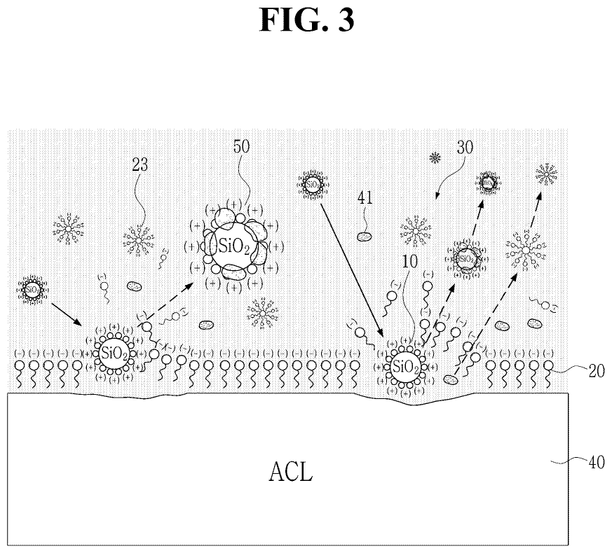

The polishing accelerator may specifically be an oligomeric type polishing accelerator. As an example, the oligomeric type polishing accelerator 20 may be shown as in FIG. 2 and may be composed of a head portion of a hydrophilic group and a tail portion of a hydrophobic group. The oligomeric type polishing accelerator 20 may have effects of not only the organic film polishing composition having a high polishing speed, but also organic film debris (CMP, 41) being discharged more smoothly by the polishing accelerator. Referring to FIG. 3, organic film debris (ACL debris) is more easily dispersed in the composition since the hydrophobic group of the polishing accelerator forms a bond with the surface of the organic film debris through hydrophobic interaction, exposing the hydrophilic group to the surface of the debris. The organic film debris may be discharged more smoothly through this.

Electrostatic attraction acts between the charges of the hydrophilic group 21 of the polishing accelerator and the abrasive particles 10, which have charges opposite to each other, and the polishing efficiency may be improved due to this. For example, when the polishing accelerator is in the form of an oligomeric type polishing accelerator as shown in FIG. 2, the hydrophilic group 21 may become the head portion of the polishing accelerator. The hydrophilic group 21 of the polishing accelerator is not particularly limited in type except for the charge relationship with the abrasive particles, and may include, for example, one or more of sulfate, sulfonate, phosphate, and carboxylate, or derivatives thereof.

In order to improve the polishing efficiency using electrostatic attraction, the surface of the abrasive particles 10 may be positively charged, and the hydrophilic group 21 of the polishing accelerator may be negatively charged. In some embodiments, the surface of the abrasive particles 10 may be negatively charged, and the hydrophilic group 21 of the polishing accelerator may be positively charged. The polishing accelerator having a positive charge in the hydrophilic group may be, for example, one or two or more selected from the group consisting of pentylammonium bromide, pentyltriethylammonium, triethylhexylammonium bromide, trimethyloctylammonium bromide, decyltrimethylammonium bromide, and trimethyl-tetradecylammonium chloride. The polishing accelerator in which the hydrophilic group has a negative charge may be, for example, one or two or more selected from the group consisting of sodium 1-heptanesulfonate monohydrate, sodium n-heptyl sulfate, sodium octyl sulfate, dipotassium octyl phosphate, cobalt(II) octyl phosphate, potassium octyl hydrogen phosphate, sodium 6-sulfonatooxyundecane, sodium hexadecyl sulfate, sulfuric acid nonadecyl=sodium salt, sodium eicosyl sulfate, sodium icosyl hydrogen sulfate, sodium docosyl sulfate, sodium tricosyl sulfate, sodium hexacosyl sulfate, sodium octacosyl sulfate, sodium triacontyl sulfate, and sodium tetratriacontyl sulfate.

When the polishing accelerator hydrophobic group 22 is oriented toward the organic film, the polishing accelerator hydrophilic group 21 is oriented outward from the organic film, and the polishing accelerator hydrophilic group 21 may be exposed to the outside. Therefore, when the charges of the polishing accelerator hydrophilic group 21 and the surface the abrasive particles 10 are opposite, the abrasive particles may be more easily attracted to the surface of the organic film due to electrostatic attraction, thereby improving the polishing efficiency using the composition.

At this time, the content of the polishing accelerator 20 is preferably 5 to 200 ppm based on the organic film polishing composition, and may be, for example, 30 to 160 ppm, 30 to 120 ppm, 50 to 100 ppm, or 50 to 90 ppm. If the content of the polishing accelerator 20 is 5 ppm or more, a decrease in the polishing efficiency may be prevented, and if the content of the polishing accelerator 20 is 200 ppm or less, the instability of the abrasive particles may be prevented, and due to this, a problem of the polishing rate decreasing or surface being scratched may be prevented or minimized.

In order to improve the polishing efficiency, the absolute value of the difference in zeta potential between the surface of the abrasive particles and the surface of the organic film containing the polishing accelerator is a factor more important than the zeta potential of the abrasive particles 10 alone. At this time, the organic film surface containing the polishing accelerator refers to an organic film surface induced to have a stronger charge by the hydrophilic group of the polishing accelerator in a state where the polishing accelerator is located on the organic film surface, and the zeta potential of the organic film surface may be induced to have a stronger negative charge by the polishing accelerator.

The zeta potential of abrasive particles or an organic film generally changes sensitively to changes in pH. Normally, as it goes toward the acidic pH region, the zeta potential may show that the positive charge (+) becomes stronger and reaches equilibrium, and as it goes toward the basic pH region, the negative charge (−) becomes stronger and reaches equilibrium. In a pH range outside the isoelectric point (IEP), which is the pH point where the zeta potential becomes 0 mV, the zeta potentials of the abrasive particles and the organic film are opposite, and the greater the difference in size, the more the polishing speed may increase.

Therefore, the zeta potential of the abrasive particles and the zeta potential of the organic film surface containing the polishing accelerator may be adjusted by adjusting the pH of the polishing composition. For example, when the organic film polishing composition has a pH of 3 to 7, the polishing efficiency of the polishing composition may be excellent. In order to realize higher polishing efficiency, the polishing efficiency may be shown to be particularly high when using an organic film polishing composition with a pH of the polishing composition of specifically 3 to 5.5, and more specifically 3.5 to 4.5. Since the problem of reduced stability of the composition due to lowered dispersibility of the abrasive may be prevented when the pH of the polishing composition is 7 or lower, excellent stability of the polishing composition may be maintained by setting the pH to 7 or lower. When the pH is 3 or higher, the organic film surface containing the polishing accelerator becomes negatively charged and the abrasive particles become positively charged, and due to this, the polishing efficiency using electrostatic attraction may increase. Therefore, in order to stably improve the polishing efficiency using zeta potential, it may be preferred that the polishing composition has a pH of 3 or higher.

In order to satisfy the above pH range of the polishing composition, at least one of acidic or basic pH regulators may be used. The acidic regulator may be, for example, one or more of nitric acid, hydrochloric acid, sulfuric acid, acetic acid, phosphoric acid, formic acid, and citric acid, but is not limited to the above examples. In addition, the basic regulator may be, for example, one or more of potassium hydroxide, sodium hydroxide, tetramethylammonium hydroxide, and tetrabutylammonium hydroxide, but is not limited to the above examples.

Zeta potentials of the abrasive particles 10 having 10 to 80 mV, specifically 10 to 60 mV, and more specifically 30 to 60 mV through the surface modification and pH control, may be the optimal range for improving the polishing efficiency. For example, when the abrasive particles have a zeta potential of 10 to 80 mV, the organic film surface containing the polishing accelerator may have a zeta potential of −60 to 0 mV, and the absolute value of the zeta potential difference between the abrasive particles and the organic film surface is 10 to 120 mV, excellent polishing efficiency may be realized. For more effective polishing efficiency, the abrasive particles may have a zeta potential of 20 to 60 mV, the organic film surface containing the polishing accelerator may have a zeta potential of −60 to −10 mV, and the absolute value of the zeta potential difference between the abrasive particles and the organic film surface may be adjusted to 30 and 120 mV. In particular, when the abrasive particles have a zeta potential of 30 to 60 mV, the organic film surface containing the polishing accelerator has a zeta potential of −60 to −30 mV, and the absolute value of the zeta potential difference between the abrasive particles and the organic film surface is 60 to 120 mV, more excellent polishing efficiency may be realized.

The organic film polishing composition according to one embodiment of the present disclosure may further include various additives to improve performance.

Specifically, biocide may be included to prevent microbial contamination. For example, it may be isothiazolinone or its derivatives, methyl isothiazolinone (MIT, MI), chloromethyl isothiazolinone (CMIT, CMI, MCI), benzisothiazolinone (BIT), octylisothiazolinone (OIT, OD, dichlorooctylisothiazolinone (DCOIT, DCOI), butylbenzisothiazolinone (BBIT), or polyhexamethylene guanidine (PHMG). The content of biocide is not limited and may be included by 0.0001 to 0.05% by weight, specifically 0.005 to 0.03% by weight based on the total weight of the organic film polishing composition.

In addition, a dispersion stabilizer, a polishing profile improver, or the like may also be included.

The dispersion stabilizer may be, for example, one or more of a combination of sodium acetate and acetic acid, a combination of sodium sulfate and sulfuric acid, citric acid, glycine, imidazole, and potassium phosphate. In particular, the combination of sodium acetate and acetic acid or the combination of sodium sulfate and sulfuric acid has excellent pH stability due to the presence of conjugate acid and conjugate base, and thus is advantageous in maintaining dispersibility. The dispersion stabilizer may be used in an amount of 500 to 8,000 ppm, specifically 600 to 5,000 ppm.

The polishing profile improver may be contained in order to improve the flatness of the polishing target film after polishing, examples thereof may include picolinic acid, picoline, dipicolinic acid, pyridine, pipecolic acid, quinolinic acid, or the like, and it may be used in an amount range of 100 to 1,000 ppm.

The solvent 30 of the organic film polishing composition according to one embodiment of the present disclosure is not particularly limited as long as it is a solvent capable of dissolving the composition, and it may be, for example, distilled water.

The polishing target of the polishing composition according to one embodiment of the present disclosure is not limited, and examples thereof may include polymer layers such as epoxy, acrylate, polyimide, and polybenzoxazole, carbon-containing films such as a spin on carbon (SOC), a spin on hardmask (SOH), and an amorphous carbon layer (ACL), metal wirings such as copper, aluminium, and tungsten, and composite films in which they exist simultaneously. The composite films may be subjected to polishing simultaneously. In particular, a high polishing speed may be realized for a very hard carbon-based film such as an amorphous carbon film or diamond-like carbon (DLC) which is formed by chemical vapor deposition (CVD).

A polishing method according to another embodiment of the present disclosure is a method of performing polishing using the organic film polishing composition, and a specific example thereof may include the steps of: uniformly applying the polishing composition according to one embodiment of the present disclosure to a polishing pad; and contacting a substrate on which a polishing target film is formed with the polishing pad to which the polishing composition is uniformly applied, thereby removing at least a portion of the polishing target film by friction (e.g., chemical and/or mechanical interactions). The polishing target film is an organic film, and a generally used polishing method may be used except that the organic film polishing composition according to the present disclosure is used as an abrasive, and is not limited to the above example.

The polishing method according to one embodiment of the present disclosure may be a polishing method that, while using the organic film polishing composition, polishes a polymer layer such as epoxy, acrylate, polyimide, or polybenzoxazole, and a carbon-containing film such as spin on carbon (SOC), spin on hardmask (SOH), or amorphous carbon layer (ACL).

The polishing speed generally increases in proportion to the contact pressure and the polishing equipment's rotational speed (e.g., in RPM). In the case of ACL, due to the very hard carbon covalent bond, polishing is performed when a high pressure of about 3 psi should have conventionally been used, and there is a problem in that polishing is not performed well at pressures lower than this. However, the polishing composition according to the present disclosure can realize a high polishing rate at a pressure of 3 psi or less, specifically even at a very low pressure of 0.5 to 1 psi, and can exhibit a significantly higher polishing speed at a pressure of 3 psi or higher.

FIG. 3 briefly shows the mechanism for polishing the organic film using an organic film polishing composition according to one embodiment of the present disclosure in which the organic film is ACL, the hydrophilic group of the polishing accelerator has a negative charge, the polishing accelerator is an oligomer type as shown in FIG. 2, and the abrasive particle surface is a positive charge. Referring to FIG. 3, the organic film 40 is polished by using the ACL as the polishing target organic film 40 so that the abrasive particles 10 approach the organic film 40 assisted by electrostatic attraction, and the organic film debris 41 generated through polishing are combined with the abrasive particles 10 to form the abrasive particles 50 combined with the organic film debris. At this time, the hydrophobic group 22 of the polishing accelerator 20 may be oriented toward the plane of the organic layer 40.

Hereinafter, preferred examples are presented to aid understanding of the present disclosure. However, the following Examples are merely illustrative of the present disclosure and the scope of the present disclosure is not limited to the following Examples.

### Preparation Example 1: Preparation of Surface-Modified Abrasive Particles

After adding the weights of the abrasive particles and the contents of the modifiers presented in Table 1 below to deionized water (D/W), a pH regulator was added in order to control the pH of the modification reaction. Afterwards, the mixture was stirred with a mechanical stirrer for 6 to 24 hours under room temperature and normal pressure conditions to prepare surface-modified abrasive particles coated with an aluminium cluster.

TABLE 1

| | Abrasive particle | Aluminium compound | pH | |
|---|---|---|---|---|
| | central portion | (modifier) | modifier | pH |
| Abrasive | Colloidal silica | Aluminium chloride | HNO₃ | 3 |
| particles 1 | | | | |
| Abrasive | Colloidal silica | Aluminium nitrate | HNO₃ | 3 |
| particles 2 | | | | |

### Preparation Example 2: Preparation of Organic Film Polishing Compositions

Organic film polishing compositions of Comparative Examples 1 and 2 and Examples 1 to 15 were prepared by mixing the abrasive particles and the polishing accelerator under room temperature and normal pressure conditions depending on the type of abrasive particles and the content of the polishing accelerator shown in Table 2 below, and adding a pH regulator under a stirring environment using a mechanical stirrer. At this time, any one of the surface-modified abrasive particles of Preparation Example 1 above, alumina, zirconia, and ceria was used as the abrasive particles, and an anionic polishing accelerator with a hydrophobic group having 8 carbon atoms was used as the polishing accelerator.

TABLE 2

| | | Content of | Abrasive |
|---|---|---|---|
| | | polishing | particles |
| | Type of | accelerator | TS |
| | abrasive particles | (ppm) | (% by weight) |
| Comparative | Abrasive particles 1 | 0 | 5 |
| Example 1 | | | |
| Comparative | Abrasive particles 2 | 0 | 3 |
| Example 2 | | | |
| Example 1 | Abrasive particles 2 | 3 | 5 |
| Example 2 | Abrasive particles 1 | 5 | 5 |
| Example 3 | Abrasive particles 2 | 10 | 5 |
| Example 4 | Abrasive particles 1 | 30 | 5 |
| Example 5 | Abrasive particles 1 | 50 | 5 |
| Example 6 | Abrasive particles 2 | 50 | 5 |
| Example 7 | Abrasive particles 2 | 90 | 5 |
| Example 8 | Abrasive particles 2 | 100 | 5 |
| Example 9 | Abrasive particles 2 | 120 | 5 |
| Example 10 | Abrasive particles 1 | 160 | 5 |
| Example 11 | Abrasive particles 1 | 200 | 5 |
| Example 12 | Abrasive particles 2 | 240 | 5 |
| Example 13 | Alumina | 100 | 5 |
| Example 14 | Zirconia | 100 | 5 |
| Example 15 | Ceria | 100 | 5 |

### Experimental Example 1: Comparison of ACL Polishing Speeds Depending on Contents of Polishing Accelerator

A 12-inch amorphous carbon layer (ACL) blanket was used as the experimental wafer, AP-300 (CTS) was used as a polisher, IC-1010 (Rohm & Haas) was used as a polishing pad, and the polishing speeds were measured using M-2000 (JA Woollam) and CMT-SR5000 (AIT) and are shown in Table 3 below. Referring to Tables 2 and 3, it can be seen that the polishing speeds are greatly improved in the case of the Examples containing a polishing accelerator. Additionally, when comparing Example 8 with Examples 13 to 15, it was confirmed that the polishing speeds were significantly improved by using the surface-modified abrasive particles.

TABLE 3

| | CMP | Polishing |
|---|---|---|
| | pressure (psi) | speed (Å/min) |
| Comparative Example 1 | 0.5 | 685 |
| Comparative Example 2 | 0.5 | 542 |
| Example 1 | 0.5 | 817 |
| Example 2 | 0.5 | 883 |
| Example 3 | 0.5 | 1070 |
| Example 4 | 0.5 | 1423 |
| Example 5 | 0.5 | 1598 |
| Example 6 | 0.5 | 1531 |
| Example 7 | 0.5 | 1473 |
| Example 8 | 0.5 | 1454 |
| Example 9 | 0.5 | 1432 |
| Example 10 | 0.5 | 1402 |
| Example 11 | 0.5 | 1358 |
| Example 12 | 0.5 | 841 |
| Example 13 | 0.5 | 999 |
| Example 14 | 0.5 | 812 |
| Example 15 | 0.5 | 784 |

### Experimental Example 2: Comparison of Colors of CMP Waste Liquids after Polishing Depending on Contents of Polishing Accelerator

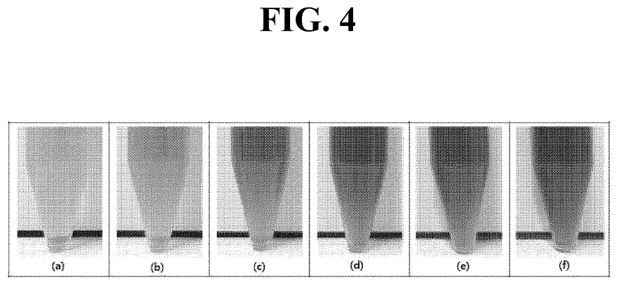

FIG. 4 compares colors of the CMP waste liquids after respectively polishing the amorphous carbon layer (ACL) with the organic film polishing compositions of Comparative Example 1A, Example 3B, Example 4C, Example 6D, Example 7E, and Example 8F prepared in Preparation Example 2 above.

Referring to FIG. 4, it can be confirmed that the colors of the CMP waste liquids using the organic film polishing compositions (b, c, d, e, and f) according to the present disclosure are very cloudy (e.g., darker), whereas the color of the CMP waste liquid in the case (a) where no polishing accelerator is used is relatively very clear (e.g., lighter), and through this, it can be seen that the ACL polishing effect of the organic film polishing composition of the present disclosure is excellent.

Referring to Table 3, it can be seen that the polishing speed of ACL increases as the concentration of the polishing accelerator increases, and is maintained at a similar polishing speed at a certain concentration or higher. However, referring to FIG. 4, it can be confirmed that the color of the CMP waste liquid continues to become darker as the concentration of the polishing accelerator increases.

Since ACL debris polished by CMP has hydrophobic surface characteristics, it is not well dispersed in a hydrophilic slurry solution so that it is difficult to discharge it to the CMP waste liquid. However, when a polishing accelerator is added, the ACL debris after CMP is changed to a hydrophilic surface by the polishing accelerator, and thus the effect of discharging it to the CMP waste liquid may increase. Such an ACL debris discharging effect may be more effective as the concentration of the polishing accelerator increases, but a preferred concentration may be selected considering the stability of the slurry solution according to the concentration influence of the polishing accelerator.

### Experimental Example 3: Comparison of ACL Polishing Speeds Depending on Carbon Numbers of Hydrophobic Group of Polishing Accelerator

Organic film polishing compositions were prepared in the same manner as the preparation method in Preparation Example 2 above except that an anionic polishing accelerator was used as the polishing accelerator, and the carbon number of the hydrophobic group of the polishing accelerator was set to be the same as that of the carbon backbone of the polishing accelerator, thereby measuring the ACL polishing speeds depending on the carbon numbers of the polishing accelerator so that they are shown in Table 4 below. Referring to Table 4, it can be seen that Examples 8 and 16 to 21, in which the polishing accelerator has a carbon number range of 5 to 30, have a higher polishing speed than Comparative Examples 3 and 4, in which the carbon number of the polishing accelerator is outside the range.

TABLE 4

| | | Content of | Carbon | | | |
|---|---|---|---|---|---|---|
| | Type of | polishing | number of | Abrasive | CMP | Polishing |
| | Abrasive | accelerator | polishing | particles TS | pressure | speed |
| | particles | (ppm) | accelerator | (% by weight) | (psi) | (Å/min) |
| Example 16 | Abrasive | 100 | 7 | 5 | 0.5 | 1157 |
| | particles 2 | | | | | |
| Example 8 | Abrasive | 100 | 8 | 5 | 0.5 | 1454 |
| | particles 2 | | | | | |
| Example 17 | Abrasive | 100 | 12 | 5 | 0.5 | 1403 |
| | particles 2 | | | | | |
| Example 18 | Abrasive | 100 | 13 | 5 | 0.5 | 1322 |
| | particles 1 | | | | | |
| Example 19 | Abrasive | 100 | 16 | 5 | 0.5 | 907 |
| | particles 2 | | | | | |
| Example 20 | Abrasive | 100 | 20 | 5 | 0.5 | 818 |
| | particles 1 | | | | | |
| Example 21 | Abrasive | 100 | 28 | 5 | 0.5 | 753 |
| | particles 1 | | | | | |
| Comparative | Abrasive | 100 | 2 | 5 | 0.5 | 693 |
| Example 3 | particles 2 | | | | | |
| Comparative | Abrasive | 100 | 34 | 5 | 0.5 | 321 |
| Example 4 | particles 2 | | | | | |

### Experimental Example 4: Comparison of ACL Polishing Speeds Depending on Charges of Abrasive Particles and Polishing Accelerator

Organic film polishing compositions were prepared in the same manner as the preparation method in Preparation Example 2 above except that ACL polishing speeds in the case in which the charges of the abrasive particles and the hydrophilic group of the polishing accelerator were opposite (Example 17) and the case in which the charges were not opposite (Comparative Examples 5 and 6) were compared and are shown in Table 5 below. Referring to Table 5, it can be seen that the ACL polishing speed is significantly lower when the charges of the abrasive particles and the hydrophilic group of the polishing accelerator have the same polarity (Comparative Examples 5 and 6), and the ACL polishing speed is greatly improved when the charges have different polarities (Example 17).

TABLE 5

| | | Comparative | Comparative |
|---|---|---|---|
| | Example 17 | Example 5 | Example 6 |
| Type of Abrasive particles | Abrasive | Abrasive | Silica |
| | particles 2 | particles 2 | particles |
| Surface charge of abrasive | + | + | − |
| particles | | | |
| Content of polishing | 100 | 100 | 100 |
| accelerator (ppm) | | | |
| Charge of hydrophilic group | − | +¹⁾ | −²⁾ |
| of polishing accelerator | | | |
| Carbon number of polishing | 12 | 12 | 12 |
| accelerator | | | |
| Abrasive particles TS | 5 | 5 | 5 |
| (% by weight) | | | |
| CMP pressure (psi) | 0.5 | 0.5 | 0.5 |
| Polishing speed (Å/min) | 1403 | 117 | 19 |

¹⁾Type of polishing accelerator: Dodecyl trimethyl ammonium chloride
²⁾Type of polishing accelerator: Same as Example 17

### Experimental Example 5: Measurement of ACL Polishing Speeds Depending on Polishing Pressures

Table 6 below shows comparative measurements of CMP pressures and ACL polishing speeds. Referring to Table 6, Example 8 shows an excellent polishing speed of 1,454 Å/min even at a low pressure of 0.5 psi, and Example 22 in which other factors except the CMP pressure are the same as Example 8, and which has a CMP pressure of 3 psi shows a significantly high polishing speed of 5,089 Å/min.

TABLE 6

| | | Content of | Carbon | | | |
|---|---|---|---|---|---|---|
| | Type of | polishing | number of | Abrasive | CMP | Polishing |
| | abrasive | accelerator | polishing | particles TS | pressure | speed |
| | particles | (ppm) | accelerator | (% by weight) | (psi) | (Å/min) |
| Example 8 | Abrasive | 100 | 8 | 5 | 0.5 | 1454 |
| | particles 2 | | | | | |
| Example 22 | Abrasive | 100 | 8 | 5 | 3 | 5089 |
| | particles 2 | | | | | |

### Experimental Example 6: Comparison of ACL Polishing Speeds Depending on Contents of Abrasive Particles

Table 7 below shows comparative measurements of ACL polishing speeds depending on the contents of abrasive particles. Referring to Table 7, even though there are differences in the contents of the abrasive particles (abrasive particles TS) for ACL polishing, all of them show excellent polishing speeds.

TABLE 7

| | | Content of | Carbon | | | |
|---|---|---|---|---|---|---|
| | Type of | polishing | number of | Abrasive | CMP | Polishing |
| | Abrasive | accelerator | polishing | particles TS | pressure | speed |
| | particles | (ppm) | accelerator | (% by weight) | (psi) | (Å/min) |
| Example | Abrasive | 100 | 8 | 1 | 0.5 | 893 |
| 23 | particles 2 | | | | | |
| Example | Abrasive | 100 | 8 | 3 | 0.5 | 1274 |
| 24 | particles 1 | | | | | |
| Example | Abrasive | 100 | 12 | 3 | 0.5 | 832 |
| 25 | particles 2 | | | | | |
| Example 8 | Abrasive | 100 | 8 | 5 | 0.5 | 1454 |
| | particles 2 | | | | | |
| Example | Abrasive | 100 | 12 | 5 | 0.5 | 1403 |
| 17 | particles 2 | | | | | |
| Example | Abrasive | 100 | 8 | 7 | 0.5 | 1484 |
| 26 | particles 2 | | | | | |
| Example | Abrasive | 100 | 8 | 10 | 0.5 | 1404 |
| 27 | particles 1 | | | | | |
| Example | Abrasive | 100 | 8 | 15 | 0.5 | 1153 |
| 28 | particles 2 | | | | | |
| Example | Abrasive | 100 | 8 | 20 | 0.5 | 943 |
| 29 | particles 1 | | | | | |
| Example | Abrasive | 100 | 8 | 22 | 0.5 | 832 |
| 30 | particles 2 | | | | | |

Although the embodiments of the present disclosure have been described in detail above, the scope of rights of the present disclosure is not limited thereto, and it will be self-evident to a person with ordinary knowledge in the technical field that various modifications and variations are possible within the scope that does not depart from the technical spirit of the present disclosure as set forth in the claims.

1. An organic film polishing composition comprising:
abrasive particles;
a polishing accelerator; and
a solvent,
wherein the polishing accelerator comprises a hydrophilic group and a hydrophobic group having 5 to 30 carbon atoms, and
wherein surface charge of the abrasive particles is opposite to charge of the hydrophilic group of the polishing accelerator.

2. The organic film polishing composition of claim 1, wherein the abrasive particles contain silica.

3. The organic film polishing composition of claim 1, wherein the abrasive particles contain abrasive particles, a surface of which is modified.

4. The organic film polishing composition of claim 3, wherein the surface of the abrasive particles has aluminium contained therein.

5. The organic film polishing composition of claim 4, wherein the abrasive particles have aluminium clusters coated on the surface thereof.

6. The organic film polishing composition of claim 1, wherein the abrasive particles are included in the organic film polishing composition by 1 to 20% by weight.

7. The organic film polishing composition of claim 1, wherein the hydrophobic group of the polishing accelerator includes a carbon backbone having 7 to 28 carbon atoms.

8. The organic film polishing composition of claim 1, wherein a surface of the abrasive particles is positively charged, and the hydrophilic group of the polishing accelerator is negatively charged.

9. The organic film polishing composition of claim 1, wherein a surface of the abrasive particles is negatively charged, and the hydrophilic group of the polishing accelerator is positively charged.

10. The organic film polishing composition of claim 1, wherein the content of the polishing accelerator is 5 to 200 ppm.

11. The organic film polishing composition of claim 1, wherein a pH of of the composition is 3 to 7.

12. The organic film polishing composition of claim 1, wherein the abrasive particles have a zeta potential of 10 to 80 mV.

13. The organic film polishing composition of claim 1, further comprising biocide.

14. The organic film polishing composition of claim 1, wherein the organic film polishing composition is configured for polishing a polymer layer.

15. The organic film polishing composition of claim 1, wherein the organic film polishing composition is configured for polishing an amorphous carbon layer.

16. A polishing method using the organic film polishing composition of claim 1.
